(19) United States
(12) Patent Application Publication
(10) Pub. No.: US 2007/0012971 A1
(43) Pub. Date: Jan. 18, 2007

(54) CMOS image sensor and manufacturing method thereof

(75) Inventor: Keun Hyuk Lim, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/488,116

(22) Filed: Jul. 14, 2006

(30) Foreign Application Priority Data
Jul. 14, 2005 (KR) 10-2005-0063736

(51) Int. Cl. H01L 31/113

(52) U.S. Cl. 257/292

(57) ABSTRACT

Provided is a CMOS image sensor and a manufacturing method thereof. The CMOS image sensor includes a gate electrode, a photodiode, a transistor region, and a light blocking material. The gate electrode is formed on a semiconductor substrate with an intervening gate insulating layer. The photodiode region is formed on one side of the gate electrode. The transistor region is formed on another side of the gate electrode. The light blocking material is formed on the transistor region to block light from reaching the transistor region.

### BACKGROUND OF THE INVENTION

1. Field of the Invention

The present invention relates to a complementary metal oxide semiconductor (CMOS) image sensor and a manufacturing method thereof.

2.Description of the Related Art

In general, a CMOS image sensor contains a photodiode and a metal oxide semiconductor (MOS) transistor within a unit pixel, and forms an image by sequentially detecting electrical signals from each unit pixel through a switching method. A CMOS image sensor according to the related art can be categorized as a 3T-type, 4T-type, 5T-type, etc., depending on the number of transistors in the unit pixel.

A 4T-type CMOS image sensor generally includes a photodiode, which is a photoelectric converter, a transfer transistor, a reset transistor, a drive transistor, and a select transistor. In a related art 4T-type CMOS image sensor having 4 transistors per pixel, electrons are formed when light enters a photodiode (PD), then when a gate electrode of the transfer transistor is turned on, the electrons are transferred to and stored in a floating diffusion region through a channel region C at the lower portion of the gate electrode. Subsequently, the electrons stored in the floating diffusion region create a voltage at a drain (or source/drain terminal) of the drive transistor.

However, light not only enters the photodiode but all regions including the floating diffusion region, so that an excess carrier may be formed and leakage may occur. In the related art 4T-type CMOS image sensor, operating precision of the photodiode may decrease because electrons/holes formed in the floating diffusion region, as opposed to electrons/holes formed in the photodiode that are typically involved in an operation of the CMOS sensor.

### SUMMARY OF THE INVENTION

Accordingly, the present invention is directed to a CMOS image sensor and a manufacturing method thereof that substantially obviate one or more problems due to limitations and disadvantages of the related art.

An object of the present invention is to provide a CMOS image sensor and a manufacturing method thereof that prevent malfunctioning of a photodiode and/or reduce operational imprecision of the image sensor by blocking light that might otherwise be incident on the floating diffusion region.

Additional advantages, objects, and features of the invention will be set forth in part in the description which follows and in part will become apparent to those having skill in the art upon examination of the following or can be learned from practice of the invention. The objectives and other advantages of the invention can be realized and attained by the structure particularly pointed out in the written description and claims hereof as well as the appended drawings.

To achieve these objects and other advantages and in accordance with the purpose of the invention, as embodied and broadly described herein, there is provided a CMOS image sensor including: a gate electrode on a semiconductor substrate with an intervening gate insulating layer; a photodiode region on a portion of the semiconductor at one side of the gate electrode; a transistor region on a portion of the semiconductor substrate at another side of the gate electrode; and a light blocking material on or over the transistor region, for blocking light from (or that might otherwise be incident on) the transistor region.

In another aspect of the present invention, there is provided a method of manufacturing a CMOS image sensor, including: forming a gate insulating layer and a gate electrode on a semiconductor substrate; forming a photodiode region on a portion of the semiconductor substrate at one side of the gate electrode; forming a transistor region on a portion of the semiconductor substrate at another side of the gate electrode; and forming a light blocking material on or over the transistor region.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle(s) of the invention. In the drawings:

FIG. 1 is a layout of a CMOS image sensor according to the first embodiment of the present invention;

FIG. 2 is a sectional view of the CMOS image sensor in FIG. 1 taken along line IV-IV′; and

FIG. 3 is a sectional view of a CMOS image sensor according to the second embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

### First Embodiment

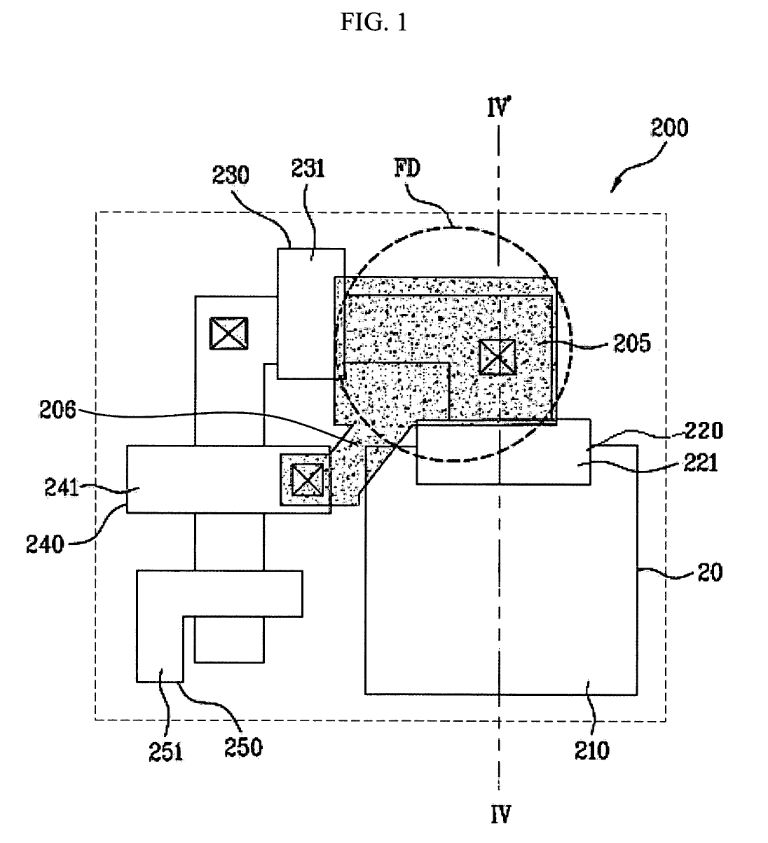

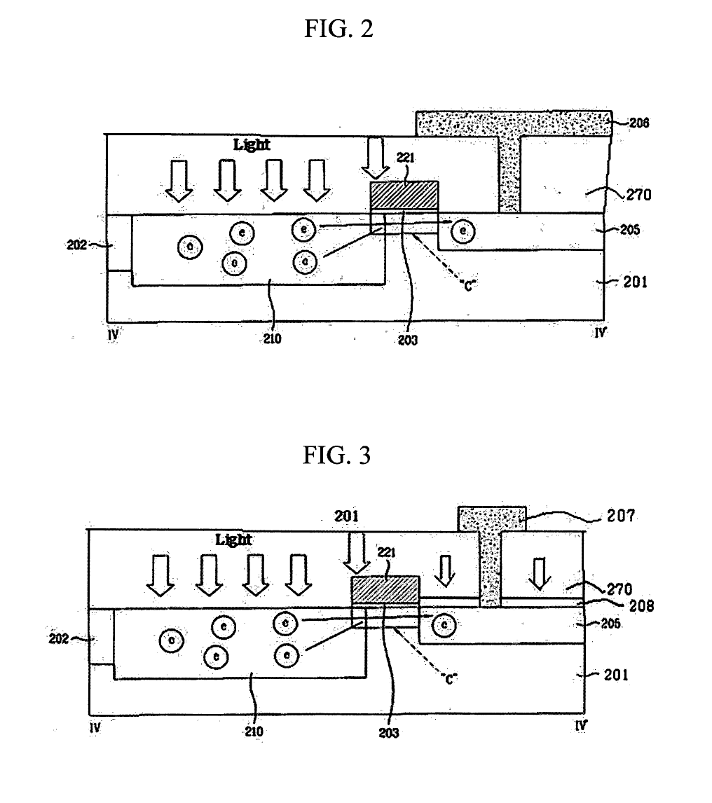

FIG. 1 is a layout of a CMOS image sensor according to the first embodiment of the present invention, and FIG. 2 is a sectional view of the CMOS image sensor in FIG. 1 taken along line IV-IV′.

In the first embodiment of the present invention, a 4T-type CMOS image sensor including four transistors per unit pixel is described. However, the first embodiment is not limited to a 4T-type CMOS image, and can include a 3T or a 5T-type CMOS image sensor.

Referring to FIG. 1, a unit pixel 200 of a CMOS unit sensor, being a photoelectric converter, can be formed in a structure including a photodiode 210 and four transistors. Here, the respective four transistors are a transfer transistor 220, a reset transistor 230, a drive transistor 240, and a select transistor 250.

The unit pixel 200 of the 4T CMOS image sensor according to the present invention has an active region 20 (defined by the thick line) and a device separating (or isolation) layer formed on or in regions other than the active region 20.

A photodiode 210 is formed by a portion of the active region 20 having a relatively large width (e.g., see region 210 in FIG. 2), and gate electrodes 221, 231, 241, and 251 of the four transistors overlap with remaining portions of the active region 20. That is, the transfer transistor 220 comprises the gate electrode 221 of the transfer transistor and the portion of the active region 20 on the side of (e.g., immediately adjacent to) gate electrode 221 opposite from photodiode 210, the reset transistor 230 comprises the gate electrode 231 of the reset transistor and portions of the active region 20 on opposite sides of (e.g., immediately adjacent to) gate electrode 231, the drive transistor 240 comprises the gate electrode 241 of the drive transistor and portions of the active region 20 on opposite sides of (e.g., immediately adjacent to) gate electrode 241, and the select transistor 250 comprises the gate electrode 251 of the select transistor and portions of the active region 20 on opposite sides of (e.g., immediately adjacent to) gate electrode 251. Here, except for the portions of the substrate below each gate electrode 221, 231, 241, and 251 (the so-called channel regions of the transistors), the active region 20 of each transistor has an impurity ion implanted therein to form source/drain (S/D) regions for each transistor.

Also, the floating diffusion (FD) region and the gate electrode 241 (and optionally, a source/drain [S/D] region) of the drive transistor 240 may be connected by a metal line 206. The metal line 206 and/or the light blocking layer 205 (particularly when the light blocking layer 205 comprises an opaque metal electrically connected to metal line 206) may overlap portions of the gate electrode 221 of the transfer transistor and the gate electrode 231 of the reset transistor. The extent of such overlap may be predetermined, to ensure complete coverage of FD region 205 by metal line 206 and/or light blocking layer 205, and thus, maximum light blocking capability across manufacturing and/or processing variations (e.g., process “corners”).

Referring now to FIG. 2, a device separating layer 202 (also known as an isolation layer or structure) is formed in a device separating region of the P⁺⁺-type semiconductor substrate 201, divided into the active region 20 (defined by the thick line) and the device separating region.

A gate insulating layer is formed on the semiconductor substrate 201 for the transfer transistor 220 in FIG. 2 (and other transistors in FIG. 1 not shown in FIG. 2), a gate electrode material is deposited thereon, and the gate electrode material is photolithographically patterned to form the transfer transistor gate electrode 221 and the gate insulating layer 203. A diffusion region 210 (e.g., an n⁻-type region) for the photodiode is formed in the surface of the semiconductor substrate 201 at or on one side of the transfer transistor gate electrode 221, typically by photolithographic (resist) masking of areas other than diffusion region 210 and implanting a low concentration of dopant ions into the unmasked area(s) of the substrate corresponding to diffusion region 210.

A floating diffusion region 205 is formed as part of the active region 20 on or at another side of the transfer transistor gate electrode 221 (e.g., the side opposite to diffusion region 210). Since the gate electrode 231 of the reset transistor, the gate electrode 241 of the drive transistor and the gate electrode 251 of the select transistor are generally formed at the same time as gate electrode 221, the portions of the active region 20 on opposite sides of (and immediately adjacent to) gate electrodes 231, 241 and 251 can be (and generally are) formed at the same time as FD region 205.

An interlayer insulating layer 270 is formed on the entire surface of the semiconductor substrate 201 including the gate electrode 221 (and other gate electrodes that may be present at that time). Contact holes are conventionally formed in insulating layer 270, and a metal line 206 that passes through the interlayer insulating layer 270 is formed in electrical contact with FD region 205, and overlapping with a predetermined portion of the gate electrode 221, to connect the floating diffusion region 205 with the gate (or source/drain region) of the drain transistor 240.

The metal line 206 may comprise or consist essentially of aluminum, molybdenum, tungsten, aluminum neodymium, an aluminum alloy such as aluminum copper (AlCu), or other opaque metals. The metal wiring 206 is not limited to a first metal wiring (e.g., first level metallization) formed on a premetal dielectric (PMD), but can be formed in part or in whole from a metal line such as a second metal line (e.g., second level metallization) or a further metal line (e.g., third, fourth, fifth level metallization, etc.), alone or in combination with a metal line in one or more other levels of metallization (e.g., by overlapping with such other metal lines).

In the 4T photodiode with 4 transistors per pixel of the CMOS image sensor according to the above-structured embodiment of the present invention, the electrons \textcircled{e} formed by light entering the photodiode are transferred to and stored in the floating diffusion region 205 through the channel region C at the lower portion of the transfer transistor gate electrode 221 when the gate electrode 221 of the transfer transistor 220 turns on (which may result from light incident on gate electrode 221). Moreover, the electrons stored in the floating diffusion region 205 may serve as the gate voltage of the drive transistor 240.

However, when light enters the unit pixel, the light is blocked by the metal lines 206 on regions other than the photodiode 210. Accordingly, the light may enter only the photodiode 210 (and some or all of the gate electrode 221) due to the metal line 206 on or over the floating diffusion region 205 blocking the light to prevent or reduce the formation of excess carriers and consequently prevent the occurrence of leakage (or reduce its effect if it occurs).

Specifically, the CMOS image sensor according to the present invention may allow electrons/holes formed substantially only in the photodiode 210 to enter the floating diffusion region 205, so that operating precision of the photodiode (and the image sensor) can be increased.

### Second Embodiment

FIG. 3 is a sectional view of a CMOS image sensor according to the second embodiment of the present invention.

The second embodiment differs from the first embodiment of the present invention in that an opaque film formed on the transistor region acts as a light blocking agent. That is, metal line 206 in the first embodiment prevent light from being absorbed by the floating diffusion region 205.In the second embodiment, however, an opaque insulating layer 204—for example, silicon nitride (Si₃N₄)—can be formed on or above the floating diffusion region 205 to block or reduce light from being absorbed by the floating diffusion region 205. At least in the area of the contact hole in insulating layer 270, metal line 207 may also help block light from being absorbed by the floating diffusion region 205.

The above-described CMOS image sensor according to the present invention has the following advantages.

First, by blocking the light entering the floating diffusion region, formation of excess carriers on the floating diffusion region can be reduced or prevented to thus prevent leakage. Second, the operating precision of the photodiode is increased because the charge on FD region 205 from electrons formed in the photodiode is proportionally greater than in the conventional image sensor described herein.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A CMOS (complementary metal oxide semiconductor) image sensor comprising:
a gate electrode on a semiconductor substrate with an intervening gate insulating layer;
a photodiode region on a first portion of the semiconductor substrate at a first side of the gate electrode;
a transistor region on a second portion of the semiconductor substrate at a second side of the gate electrode; and
a light blocking material on or over the transistor region, configured to block light from the transistor region.

2. The CMOS image sensor according to claim 1, wherein the gate electrode is part of a transfer transistor.

3. The CMOS image sensor according to claim 1, wherein the transistor region also serves as a floating diffusion region.

4. The CMOS image sensor according to claim 1, wherein the light blocking material comprises an opaque metal line.

5. The CMOS image sensor according to claim 4, wherein the metal line is on a dielectric layer.

6. The CMOS image sensor according to claim 5, wherein the light blocking material comprises a material selected from the group consisting of aluminum, molybdenum, aluminum neodymium, and AlCu (aluminum copper).

7. The CMOS image sensor according to claim 1, wherein the light blocking material overlaps a predetermined portion of the gate electrode.

8. The CMOS image sensor according to claim 1, wherein the gate electrode is part of a transfer transistor, and the semiconductor substrate has the transfer transistor, a reset transistor, a drive transistor, and a select transistor thereon; and
the light blocking material comprises a metal line that overlaps a portion of the gate electrode of the transfer transistor and a portion of a gate electrode of the reset transistor.

9. The CMOS image sensor according to claim 1, wherein the light blocking material comprises an opaque insulating layer on or over the transistor region.

10. The CMOS image sensor according to claim 9, wherein the opaque insulating layer comprises a silicon nitride layer.

11. A method of manufacturing a CMOS image sensor, the method comprising:
forming a gate insulating layer and a gate electrode on a semiconductor substrate;
forming a photodiode region on a first portion of the semiconductor substrate at a first side of the gate electrode;
forming a transistor region on a second portion of the semiconductor substrate at a second side of the gate electrode; and
forming a light blocking material on or over the transistor region.

12. The method according to claim 11, wherein the gate electrode is part of a transfer transistor.

13. The method according to claim 11, further comprising forming an insulating layer on or over the photodiode region, wherein the light blocking material comprises a metal line formed on the interlayer insulating layer.

14. The method according to claim 13, wherein the insulating layer comprises a PMD (premetal dielectric), and the metal line is in a first level of metallization.

15. The method according to claim 13, wherein the metal line comprises a material selected from the group consisting of aluminum, molybdenum, aluminum neodymium, and AlCu (aluminum copper).

16. The method according to claim 11, wherein the light blocking material overlaps a predetermined portion of the gate electrode.

17. The method according to claim 11, further comprising forming a transfer transistor, a reset transistor, a drive transistor, and a select transistor on the semiconductor substrate,
wherein the gate electrode is part of the transfer transistor, and the light blocking material comprises a metal line that overlaps a portion of the gate electrode of the transfer transistor and a portion of a gate electrode of the reset transistor.

18. The method according to claim 11, wherein the light blocking material comprises an opaque insulating layer.

19. The method according to claim 11, wherein the light blocking material comprises an opaque insulating layer; and
the method further comprises forming an insulating layer on or over an entire surface of the opaque insulating layer.

20. The method according to claim 18, wherein the opaque insulating layer comprises a silicon nitride layer.
